(19) United States
(12) Patent Application Publication
(10) Pub. No.: US 2008/0088017 A1
(43) Pub. Date: Apr. 17, 2008

(54) Semiconductor integrated circuit device

(75) Inventor: Shoji Saito, Daito (JP)

Correspondence Address: BACON & THOMAS, PLLC, 625 SLATERS LANE, FOURTH FLOOR, ALEXANDRIA, VA, 22314, US

(73) Assignee: FUNAI Electric Co., Ltd., Daito (JP)

(21) Appl. No.: 11/907,552

(22) Filed: Oct. 15, 2007

(30) Foreign Application Priority Data
Oct. 14, 2006 (JP) 2006-280798

(51) Int. Cl. H01L 23/488

(52) U.S. Cl. 257/738; 257/E23.023

(57) ABSTRACT

An unoccupied space on a BGA package is utilized effectively to reduce cost. In a semiconductor integrated circuit device in which the lower surface 1a of a BGA package 1 has many ball-shaped terminals 2 arranged in a central section D1 and a peripheral section D2 thereon in a grid pattern of multiple lines and an approximately rectangular-shaped hollow section D3 is formed between the central section D1 and the peripheral section D2 on the lower surface 1a, while a mounting area E is formed in place on one surface 3a of a printed-wiring substrate 3 in such a manner as to face the BGA package 1, the mounting area E including many lands 5 arranged in a central area E1 and a peripheral area E2 thereon in a grid pattern of multiple lines in such a manner as to face the respective ball-shaped terminals 2, and an approximately rectangular-shaped middle area E3 is formed between the central area E1 and the peripheral area E2 in the mounting area E, where the BGA package 1 is adapted to be mounted on the one surface 3a of the printed-wiring substrate 3, a peripheral circuit C including various electronic components Ca is provided in the middle area E3 in the mounting area E.

### BACKGROUND OF THE INVENTION

1. Field of the Invention

The present invention relates to a semiconductor integrated circuit device to be used in, for example, a disk apparatus (e.g. DVD recorder or DVD player) and, particularly, in which an unoccupied space on a BGA (Ball Grid Array) package is utilized effectively to reduce cost.

2. Description of the Related Art

A conventional semiconductor integrated circuit device technique is disclosed in Japanese Patent Laid-Open Publication No. 2000-299407. In this technique, as shown in the side view of FIG. 5 (a) and the view of FIG. 5 (b) taken along the arrows C-C, the lower surface 1a of a BGA package 1 incorporating a semiconductor chip has many ball-shaped terminals 2 arranged thereon in a grid pattern of multiple lines (three lines in this example) n1 to n3, while a mounting area E is formed in place on one surface 3a of a printed-wiring substrate 3 in such a manner as to face the BGA package 1. The mounting area E includes many lands 5 arranged thereon in a grid pattern of multiple lines (three lines in this example) n1 to n3 in such a manner as to face the respective ball-shaped terminals 2. The BGA package 1 is mounted on the surface 3a of the printed-wiring substrate 3 by soldering each ball-shaped terminal 2 on the BGA package 1 to each land 5 in a reflow furnace.

Although the arrangement above includes a small number of ball-shaped terminals 2 and lines n1 to n3 to show the semiconductor integrated circuit device schematically, the BGA package 1 practically has several hundreds (about 400 for example) of ball-shaped terminals 2 in accordance with the size of the semiconductor integrated circuit. A conventional example will be described with reference to FIGS. 6 to 9.

FIG. 6 is a perspective view of a semiconductor integrated circuit device; FIG. 7 is an exploded perspective view of the semiconductor integrated circuit device; FIG. 8 is a view taken along the arrows D-D; and FIG. 9 is an enlarged view taken along the arrows E-E, where since the number of ball-shaped terminals 2 is large, the ball-shaped terminals 2 are divided into two groups and accordingly the lower surface 1a of the BGA package 1 is partitioned into a central section D1 and a peripheral section D2. The sections D1 and D2 include the ball-shaped terminals 2 belonging to the respective groups and arranged thereon in a grid pattern of multiple lines (five lines in the central section D1 and six lines in the peripheral section D2) n1 to n5 and n6 to n11, and an approximately rectangular-shaped hollow section D3 is formed between the central section D1 and the peripheral section D2 on the lower surface 1a.

Also, a mounting area E is formed in central place on one surface 3a of a printed-wiring substrate 3 in such a manner as to face the BGA package 1. The central area E1 and the peripheral area E2 in the mounting area E include many lands 5 arranged thereon in a grid pattern of multiple lines (five lines in the central area E1 and six lines in the peripheral area E2) n1 to n5 and n6 to n11 in such a manner as to face the respective ball-shaped terminals 2, and an approximately rectangular-shaped middle area E3 is formed between the central area E1 and the peripheral area E2 in the mounting area E.

Further, as shown in FIGS. 7 and 8, peripheral circuits C including various electronic components Ca (chip capacitors and chip resistors, etc.) are provided outside the mounting area E on the surface 3a of the printed-wiring substrate 3. It is noted that in FIG. 7, the reference F indicates an outer integrated circuit extending outside of the mounting area E and the peripheral circuits C on the surface 3a of the printed-wiring substrate 3.

In the conventional arrangement above, when the BGA package 1 is mounted on the surface 3a of the printed-wiring substrate 3, a rectangular doughnut-shaped space K constituted between the hollow section D3 and the middle area E3 is left unutilized effectively, as shown in FIG. 9. On the other hand, the peripheral circuits C including various electronic components Ca (chip capacitors and chip resistors, etc.) are provided outside the mounting area E, which increases the area (a×b) of the printed-wiring substrate 3 for the peripheral circuits C (refer to FIG. 6), resulting in an increase in cost.

### SUMMARY OF THE INVENTION

The present invention has been made in consideration of the above-described conventional disadvantages, and an object thereof is to provide a semiconductor integrated circuit device in which an unoccupied space on a BGA package is utilized effectively to reduce cost.

In order to achieve the foregoing object, a first aspect of the present invention is a semiconductor integrated circuit device in which the lower surface of a BGA package has many ball-shaped terminals arranged in a central section and a peripheral section thereon in a grid pattern of multiple lines and an approximately rectangular-shaped hollow section is formed between the central section and the peripheral section on the lower surface, while a mounting area is formed in place on one surface of a printed-wiring substrate in such a manner as to face the BGA package, the mounting area including many lands arranged in a central area and a peripheral area thereon in a grid pattern of multiple lines in such a manner as to face the respective ball-shaped terminals, and an approximately rectangular-shaped middle area is formed between the central area and the peripheral area in the mounting area, where the BGA package is adapted to be mounted on the one surface of the printed-wiring substrate by soldering each ball-shaped terminal on the BGA package to each land, wherein the printed-wiring substrate includes a peripheral circuit including various electronic components and relocated from outside the mounting area to the middle area in the mounting area.

A second aspect of the present invention is a semiconductor integrated circuit device in which the lower surface of a BGA package has many ball-shaped terminals arranged in a central section and a peripheral section thereon in a grid pattern of multiple lines and an approximately rectangular-shaped hollow section is formed between the central section and the peripheral section on the lower surface, while a mounting area is formed in place on one surface of a printed-wiring substrate in such a manner as to face the BGA package, the mounting area including many lands arranged in a central area and a peripheral area thereon in a grid pattern of multiple lines in such a manner as to face the respective ball-shaped terminals, and an approximately rectangular-shaped middle area is formed between the central area and the peripheral area in the mounting area, where the BGA package is adapted to be mounted on the one surface of the printed-wiring substrate by soldering each ball-shaped terminal on the BGA package to each land, wherein the printed-wiring substrate includes a peripheral circuit including various electronic components and provided in the middle area in the mounting area.

In a third aspect of the present invention, the second aspect is arranged in such a manner that the peripheral circuit including the various electronic components is relocated from outside the mounting area on the printed-wiring substrate to the middle area in the mounting area.

In accordance with the first aspect, the peripheral circuit including the various electronic components is provided in the middle area in the mounting area on the printed-wiring substrate, and when the BGA package is mounted on the printed-wiring substrate, the peripheral circuit including the various electronic components is to be housed in the hollow section on the BGA package, which allows the conventionally unoccupied space on the BGA package to be utilized effectively.

Also, since the peripheral circuit including the various electronic components is relocated from outside the mounting area to the middle area in the mounting area, the relocation can accordingly reduce the area of the printed-wiring substrate and therefore can reduce cost.

Further, the efficient circuit design for electronic components such as chip capacitors and chip resistors can be achieved easily by arranging the electronic components in the middle area in the mounting area. In particular, arranging bypass capacitors among the electronic components as close as possible to the IC allows for noise reduction.

In accordance with the second aspect, the peripheral circuit including the various electronic components is provided in the middle area in the mounting area on the printed-wiring substrate, and when the BGA package is mounted on the printed-wiring substrate, the peripheral circuit including the various electronic components is to be housed in the hollow section on the BGA package, which allows the conventionally unoccupied space on the BGA package to be utilized effectively.

Also, the efficient circuit design for electronic components such as chip capacitors and chip resistors can be achieved easily by arranging the electronic components in the middle area in the mounting area. In particular, arranging bypass capacitors among the electronic components as close as possible to the IC allows for noise reduction.

In accordance with the third aspect, since the peripheral circuit including the various electronic components is relocated from outside the mounting area to the middle area in the mounting area, the relocation can accordingly reduce the area of the printed-wiring substrate and therefore can reduce cost.

### BRIEF DESCRIPTION OF THE DRAWINGS

FIG. 1 is a perspective view of a semiconductor integrated circuit device according to an embodiment of the present invention;

FIG. 2 is an exploded perspective view of the semiconductor integrated circuit device;

FIG. 3 is a view taken along the arrows A-A in FIG. 1;

FIG. 4 is an enlarged view taken along the arrows B-B in FIG. 3;

FIG. 5 (a) is a side view showing a conventional example and FIG. 5 (b) is a view taken along the arrows C-C in FIG. 5 (a);

FIG. 6 is a perspective view showing another conventional example;

FIG. 7 is an exploded perspective view of the example;

FIG. 8 is a view taken along the arrows D-D in FIG. 6; and

FIG. 9 is an enlarged view taken along the arrows E-E in FIG. 8.

### DESCRIPTION OF THE PREFERRED EMBODIMENTS

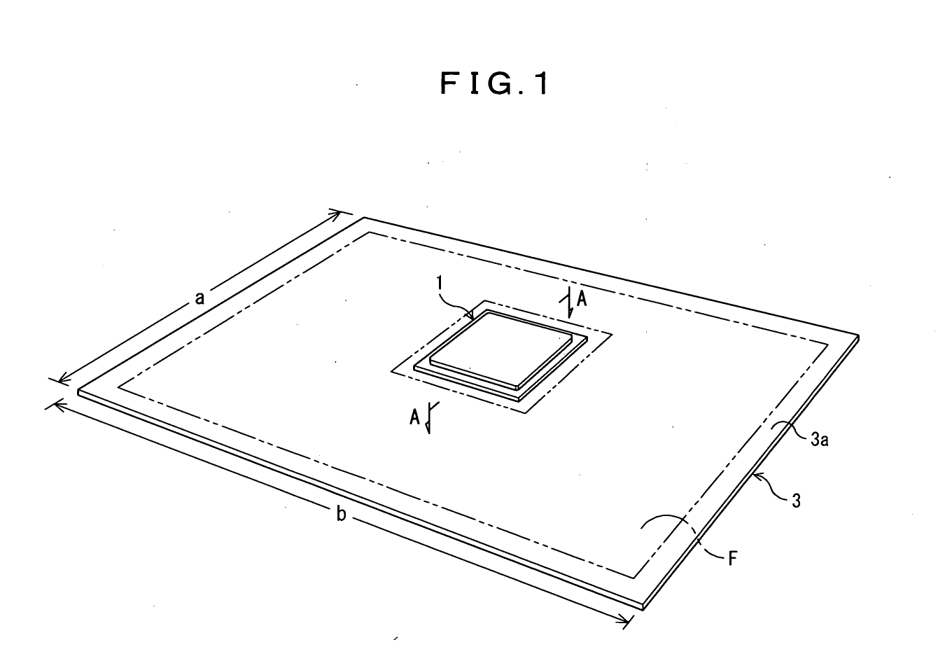

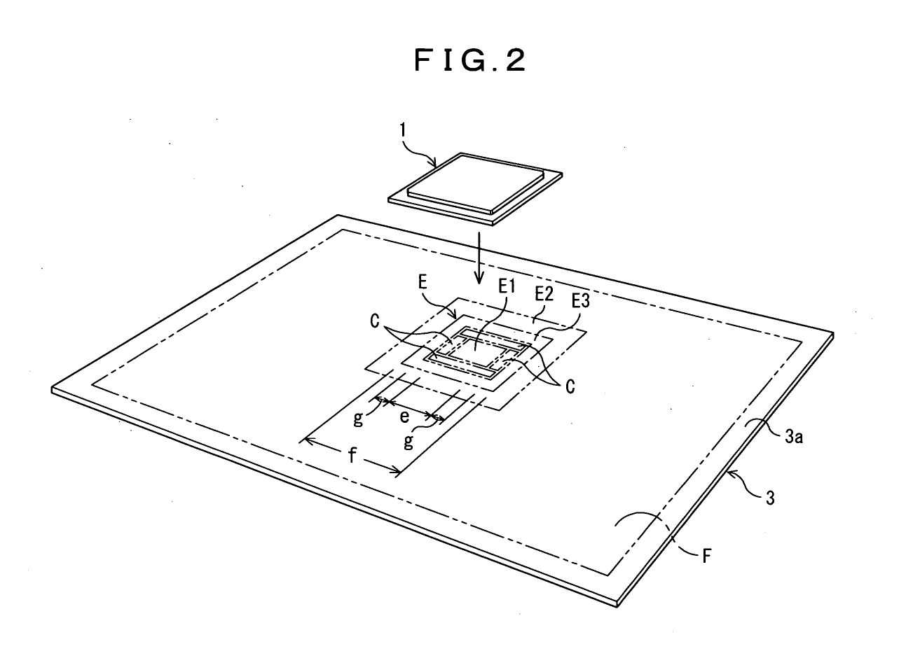

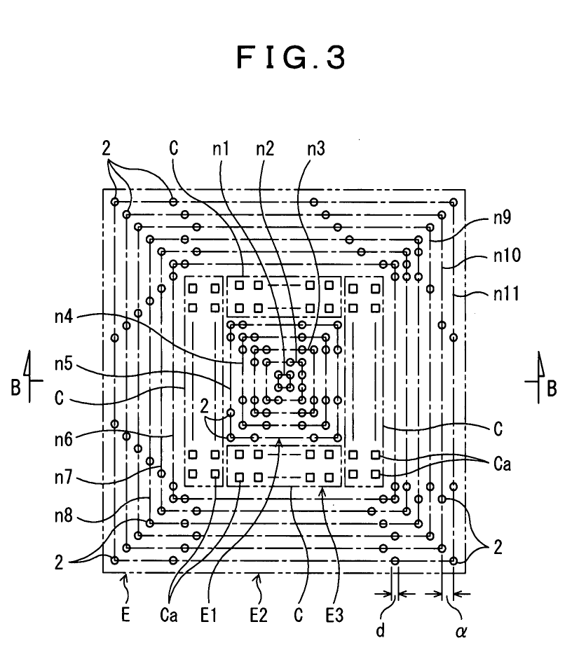

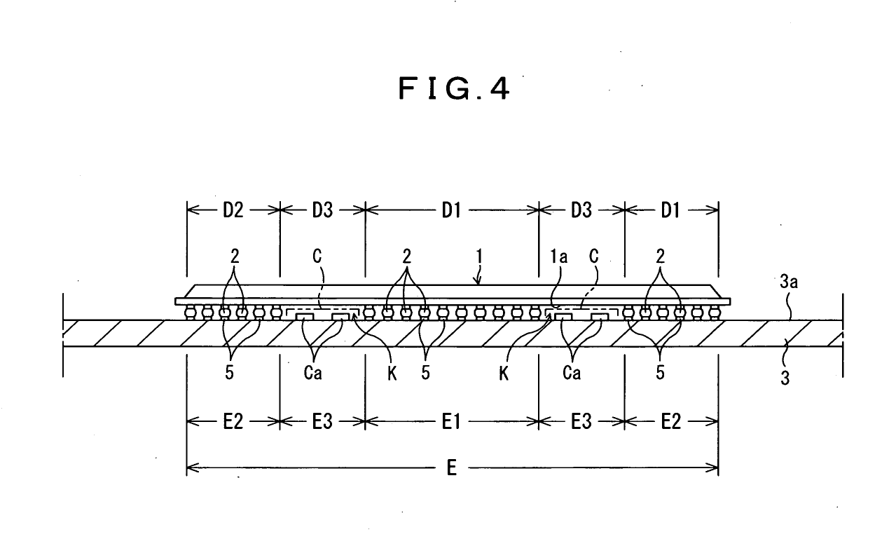

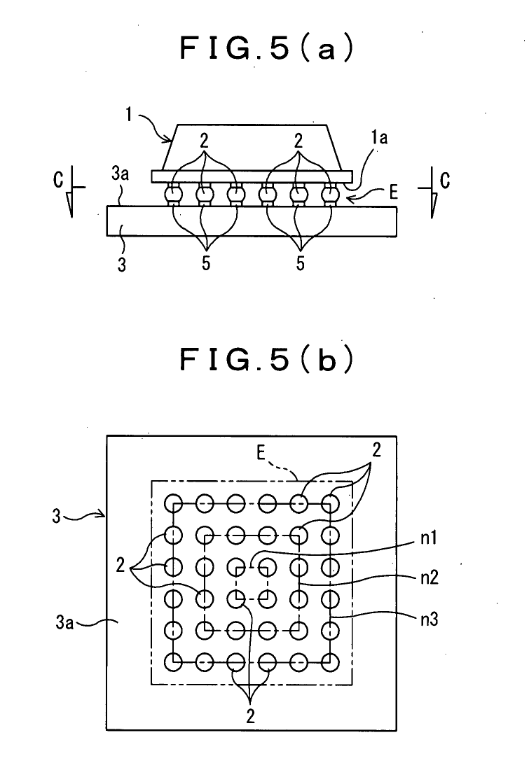

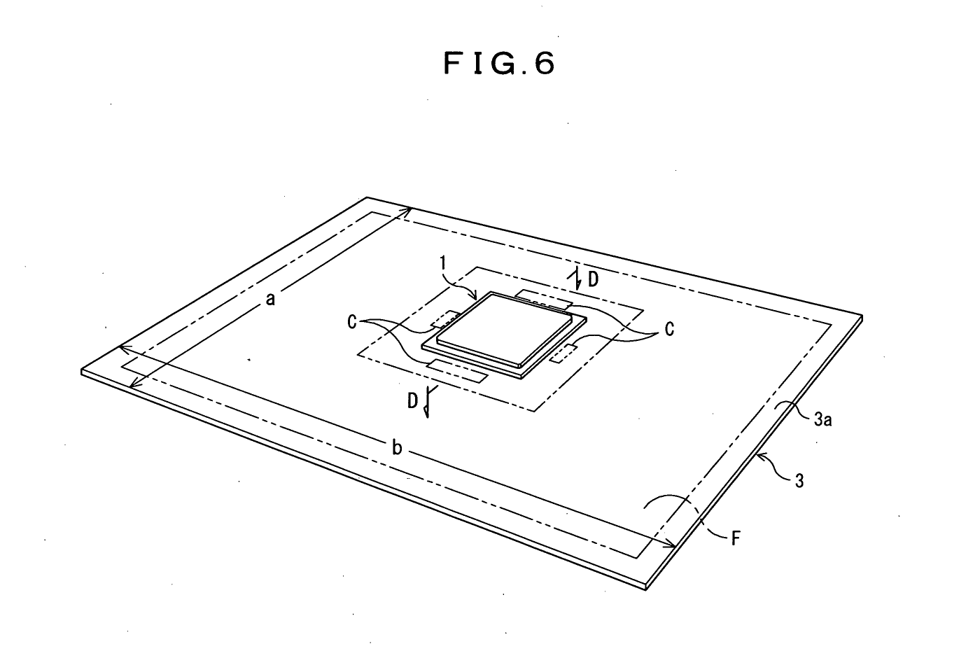

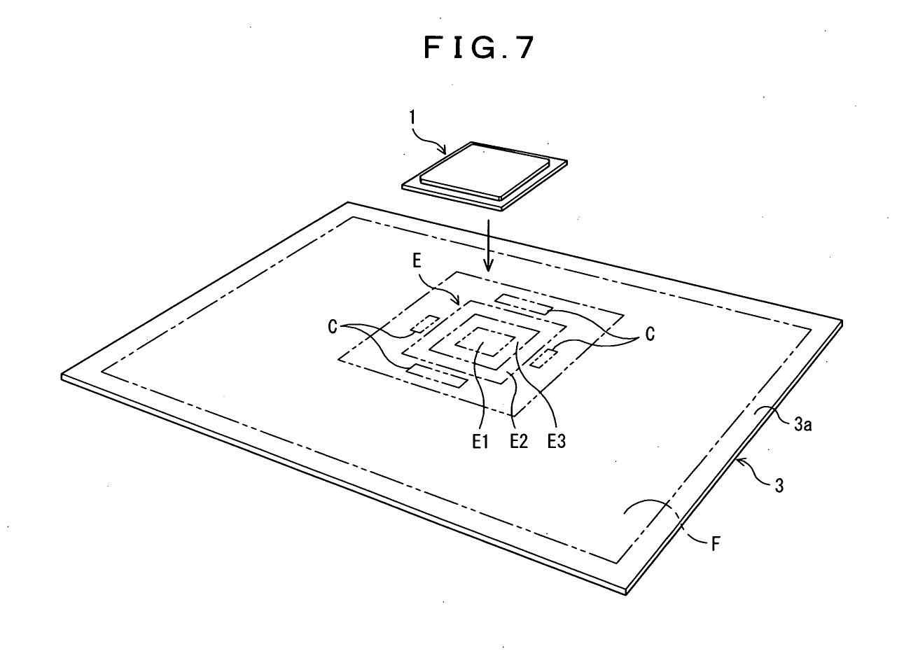

FIGS. 1 to 4 show a semiconductor integrated circuit device to be used in, for example, a disk apparatus (e.g. DVD recorder or DVD player) according to an embodiment of the present invention. FIG. 1 is a perspective view of the semiconductor integrated circuit device; FIG. 2 is an exploded perspective view of the semiconductor integrated circuit device; FIG. 3 is a view taken along the arrows A-A; and FIG. 4 is an enlarged view taken along the arrows B-B, where peripheral circuits C including various electronic components Ca (chip capacitors and chip resistors, etc.) that are provided outside the mounting area E as in the conventional example shown in FIG. 6 are relocated to the middle area E3 in the mounting area E. Since the arrangements other than those above are approximately the same as those shown in FIGS. 6 to 9, identical components are designated by the same reference numerals to omit the descriptions thereof.

As a specific dimensional example, the diameter “d” of each ball-shaped terminal 2 is 0.6 mm and the clearance “□” between ball-shaped terminals 2 is 1 mm in FIG. 3. Also, in FIG. 2, the length (and width) “e” of the central area E1 is 9 mm, the length (and width) “f” of the peripheral area E2 is 30 mm, and the width “g” of the middle area E3 is 4.5 mm. Further, each peripheral circuit C employs, for example, an electronic component Ca having a width of 0.6 mm, length of 0.3 mm, and height of 0.23 mm and/or another electronic component Ca having a width of 0.4 mm, length of 0.2 mm, and height of 0.13 mm.

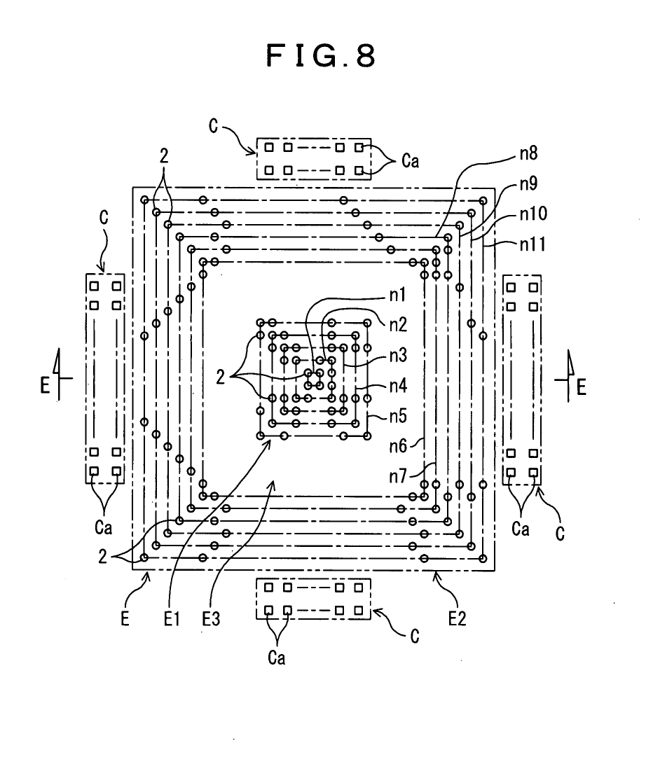

In accordance with the arrangement above, peripheral circuits C including various electronic components Ca are provided in the middle area E3 in the mounting area E on the printed-wiring substrate 3, and when the BGA package 1 is mounted on the printed-wiring substrate 3, the peripheral circuits C are to be housed in the hollow section D3 on the BGA package 1 as shown in FIGS. 3 and 4, which allows the conventionally unoccupied space on the BGA package 1 to be utilized effectively (refer to FIGS. 8 and 9).

Also, since the peripheral circuits C including the various electronic components Ca that are located outside the mounting area E as in the conventional example shown in FIG. 6 are relocated to the middle area E3 in the mounting area E (refer to FIG. 1), the relocation can accordingly reduce the area (a×b) of the printed-wiring substrate 3 and therefore can reduce cost.

Further, the efficient circuit design for electronic components Ca such as chip capacitors and chip resistors can be achieved easily by arranging the electronic components Ca in the middle area E3 in the mounting area E. In particular, arranging bypass capacitors among the electronic components Ca as close as possible to the IC allows for noise reduction.

Although the above-described embodiment employs an arrangement of relocating the peripheral circuits C from outside the mounting area E on the printed-wiring substrate 3 to the middle area E3 in the mounting area E, the present invention is not restricted thereto. Various electronic components Ca in the outer integrated circuit F may be relocated to the middle area E3 in the mounting area E, for example.

What is claimed is:

1. A semiconductor integrated circuit device in which the lower surface of a BGA package has many ball-shaped terminals arranged in a central section and a peripheral section thereon in a grid pattern of a plurality of lines and an approximately rectangular-shaped hollow section is formed between said central section and said peripheral section on the lower surface, while a mounting area is formed in place on one surface of a printed-wiring substrate in such a manner as to face said BGA package, said mounting area including many lands arranged in a central area and a peripheral area thereon in a grid pattern of a plurality of lines in such a manner as to face said respective ball-shaped terminals, and an approximately rectangular-shaped middle area is formed between said central area and said peripheral area in said mounting area, where said BGA package is adapted to be mounted on said one surface of said printed-wiring substrate by soldering each ball-shaped terminal on said BGA package to each land, wherein
said printed-wiring substrate comprises a peripheral circuit including various electronic components and relocated from outside said mounting area to said middle area in said mounting area.

2. A semiconductor integrated circuit device in which the lower surface of a BGA package has many ball-shaped terminals arranged in a central section and a peripheral section thereon in a grid pattern of a plurality of lines and an approximately rectangular-shaped hollow section is formed between said central section and said peripheral section on the lower surface, while a mounting area is formed in place on one surface of a printed-wiring substrate in such a manner as to face said BGA package, said mounting area including many lands arranged in a central area and a peripheral area thereon in a grid pattern of a plurality of lines in such a manner as to face said respective ball-shaped terminals, and an approximately rectangular-shaped middle area is formed between said central area and said peripheral area in said mounting area, where said BGA package is adapted to be mounted on said one surface of said printed-wiring substrate by soldering each ball-shaped terminal on said BGA package to each land, wherein
said printed-wiring substrate comprises a peripheral circuit including various electronic components and provided in said middle area in said mounting area.

3. The semiconductor integrated circuit device according to claim 2, wherein said peripheral circuit including said various electronic components is relocated from outside said mounting area on said printed-wiring substrate to said middle area in said mounting area.
